(19) United States
(12) Patent Application Publication
(10) Pub. No.: US 2025/0063749 A1
(43) Pub. Date: Feb. 20, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Chih-Lun LU, New Taipei (TW); Hsiu-Ling CHEN, Taoyuan (TW); Chen-Wei PAN, Hsinchu (TW)

(21) Appl. No.: 18/234,481

(22) Filed: Aug. 16, 2023

(51) Int. Cl. H01L 29/66; H01L 21/8234

(52) U.S. Cl. CPC H01L 29/66795; H01L 21/823431; H01L 21/823481; H01L 29/66545; H01L 27/0886; H01L 29/7851

(57) ABSTRACT

A method for forming a semiconductor device structure is described. In some embodiments, the method includes forming a gate electrode, forming a mask structure over the gate electrode, patterning the mask structure to form an opening, and performing a first etch process on the gate electrode by applying a first source power and a first bias power with a first pulsing scheme. The first bias power has a first frequency to control etching along a lateral direction. The method further includes performing a second etch process on the mask structure exposed within the opening by applying a second source power and a second bias power with a second pulsing scheme, and the second bias power has a second frequency to control etching along a vertical direction. The first and second frequencies are substantially different.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3A-B, 4A-D, 5A-C, 6A-C, 7A-C, and 8A-C are various views of respective intermediate structures at intermediate stages in an example process of forming a semiconductor device structure including one or more FinFETs, in accordance with some embodiments.

FIG. 9 illustrates a pulsing scheme used in an etching process in accordance with some embodiments.

FIGS. 10-12 are cross-sectional views at various instances of processing corresponding to cross-section A-A in FIG. 4D, in accordance with some embodiments.

FIG. 13 illustrates a pulsing scheme used in an etching process in accordance with some embodiments.

FIGS. 14-17 are cross-sectional views at various instances of processing corresponding to cross-section A-A in FIG. 4D, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices and fabrication methods, and more particularly to fabricating semiconductor devices using a cut metal gate (CMG) process. A CMG process refers to a fabrication process where after a gate electrode (e.g., a metal gate) replaces a dummy gate structure (e.g., a polysilicon gate), the gate electrode is cut (e.g., by an etching process) to separate the gate electrode into two or more portions. Each portion functions as a gate electrode for an individual transistor. An isolation material is subsequently filled into openings between adjacent portions of the gate electrode. In order to minimize a void formed in the isolation material, a main etch step and a final breakthrough etch step are performed to form the openings.

In some instances, in the described embodiments, various losses, e.g., in height, to the illustrated structures may occur during processing. These losses may not be expressly shown in the figures or described herein, but a person having ordinary skill in the art will readily understand how such losses may occur. Such losses may occur as a result of a planarization process such as a chemical mechanical polish (CMP), an etch process when, for example, the structure realizing the loss is not the primary target of the etching, and other processes.

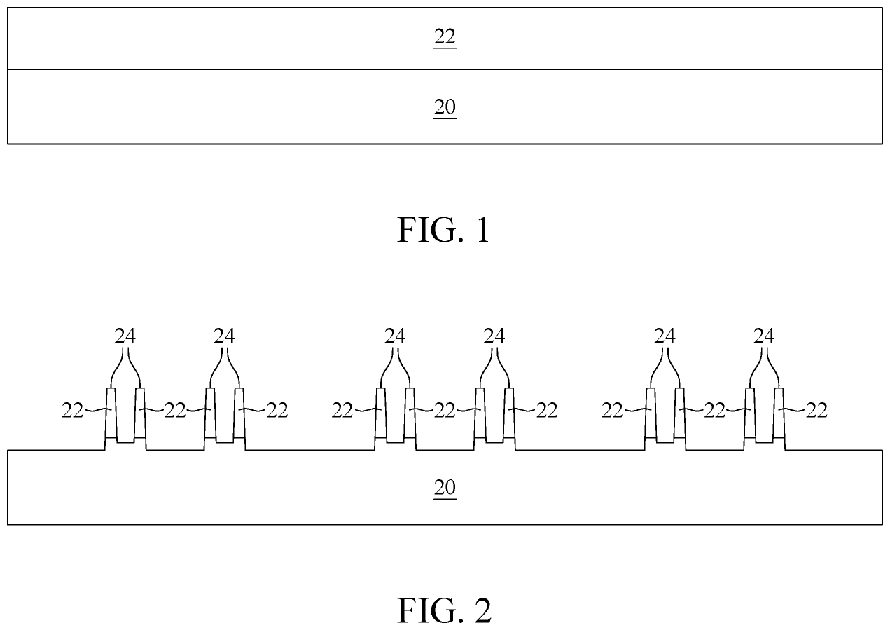

FIGS. 1, 2, 3A-B, 4A-D, and 5A-C through 8A-C are various views of respective intermediate structures during intermediate stages in an example process of forming a semiconductor device structure including one or more FinFETs, in accordance with some embodiments. FIG. 1 illustrates, in a cross-sectional view, a semiconductor substrate 20 with a stressed semiconductor layer 22 formed thereover. The semiconductor substrate 20 may be or include a bulk semiconductor substrate, a semiconductor-on-insulator (SOI) substrate, or the like, which may be doped (e.g., with a p-type or an n-type dopant) or undoped. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the semiconductor substrate may include an elemental semiconductor such as silicon (Si) and germanium (Ge); a compound semiconductor including silicon carbide, gallium arsenic, gallium phosphide, indium phosphide, indium arsenide, or indium antimonide; an alloy semiconductor including SiGe, GaAsP, AlInAs, AlGaAs, GaInAs, GaInP, or GaInAsP; or a combination thereof.

The stressed semiconductor layer 22 can have a compressive stress or a tensile stress. In some examples, the stressed semiconductor layer 22 is stressed as a result of heteroepitaxial growth on the semiconductor substrate 20. For example, heteroepitaxial growth generally includes epitaxially growing a grown material having a natural lattice constant that is different from the lattice constant of the substrate material at the surface on which the grown material is epitaxially grown. Pseudomorphically growing the grown material on the substrate material can result in the grown material having a stress. If the natural lattice constant of the grown material is greater than the lattice constant of the substrate material, the stress in the grown material can be compressive, and if the natural lattice constant of the grown material is less than the lattice constant of the substrate material, the stress in the grown material can be tensile. For example, pseudomorphically growing SiGe on relaxed silicon can result in the SiGe having a compressive stress, and pseudomorphically growing SiC on relaxed silicon can result in the SiC having a tensile stress.

The stressed semiconductor layer 22 can be or include silicon, silicon germanium (Si₁₋ₓGeₓ, where x can be between approximately 0 and 100), silicon carbide, pure or substantially pure germanium, a III-V compound semiconductor, a II-VI compound semiconductor, or the like. For example, materials for forming a III-V compound semiconductor include InAs, AlAs, GaAs, InP, GaN, InGaAs, InAlAs, GaSb, AlSb, AlP, GaP, and the like. Further, the stressed semiconductor layer 22 can be epitaxially grown using metal-organic chemical vapor deposition (MOCVD), molecular beam epitaxy (MBE), liquid phase epitaxy (LPE), vapor phase epitaxy (VPE), selective epitaxial growth (SEG), the like, or a combination thereof on the semiconductor substrate 20. A thickness of the stressed semiconductor layer 22 can be in a range from about 30 nm to about 50 nm.

FIG. 2 illustrates, in a cross-sectional view, the formation of fins 24 in the stressed semiconductor layer 22 and/or semiconductor substrate 20. In some examples, a mask (e.g., a hard mask) is used in forming the fins 24. For example, one or more mask layers are deposited over the stressed semiconductor layer 22, and the one or more mask layers are then patterned into the mask. In some examples, the one or more mask layers may include or be silicon nitride, silicon oxynitride, silicon carbide, silicon carbon nitride, the like, or a combination thereof, and may be deposited by chemical vapor deposition (CVD), physical vapor deposition (PVD), atomic layer deposition (ALD), or another deposition technique. The one or more mask layers may be patterned using photolithography. For example, a photo resist can be formed on the one or more mask layers, such as by using spin-on coating, and patterned by exposing the photo resist to light using an appropriate photomask. Exposed or unexposed portions of the photo resist may then be removed depending on whether a positive or negative resist is used. The pattern of the photo resist may then be transferred to the one or more mask layers, such as by using a suitable etch process, which forms the mask. The etch process may include a reactive ion etch (RIE), neutral beam etch (NBE), inductive coupled plasma (ICP) etch, the like, or a combination thereof. The etch process may be anisotropic. Subsequently, the photo resist is removed in an ashing or wet strip processes, for example.

Using the mask, the stressed semiconductor layer 22 and/or semiconductor substrate 20 may be etched such that trenches are formed between neighboring pairs of fins 24 and such that the fins 24 protrude from the semiconductor substrate 20. In some embodiments, each fin 24 has a height ranging from about 115 nm to about 120 nm. The etch process may include a RIE, NBE, ICP etch, the like, or a combination thereof. The etch process may be anisotropic. The trenches may be formed to a depth in a range from about 80 nm to about 150 nm from the top surface of the stressed semiconductor layer 22. In some embodiments, the trench between a pair of fins 24 may be substantially shallower than the trench between neighboring pairs of fins 24 due to the loading effect, as shown in FIG. 2. In some embodiments where the trenches have different depths, the different depths may not be explicitly illustrated.

Although examples described herein are in the context of stress engineering for the fins 24 (e.g., the fins 24 include respective portions of the stressed semiconductor layer 22), other examples may not implement such stress engineering. For example, the fins 24 may be formed from a bulk semiconductor substrate (e.g., semiconductor substrate 20) without a stressed semiconductor layer. Also, the stressed semiconductor layer 22 may be omitted from subsequent figures; this is for clarity of the figures. In some embodiments where such a stress semiconductor layer is implemented for stress engineering, the stressed semiconductor layer 22 may be present as part of the fins 24 even if not explicitly illustrated; and in some embodiments where such a stress semiconductor layer is not implemented for stress engineering, the fins 24 may be formed from the semiconductor substrate 20.

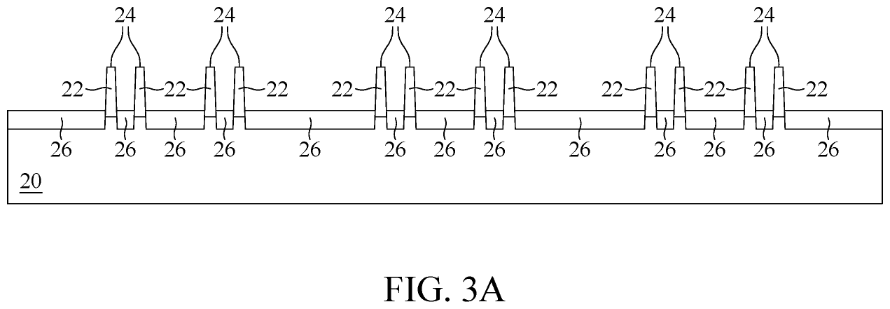

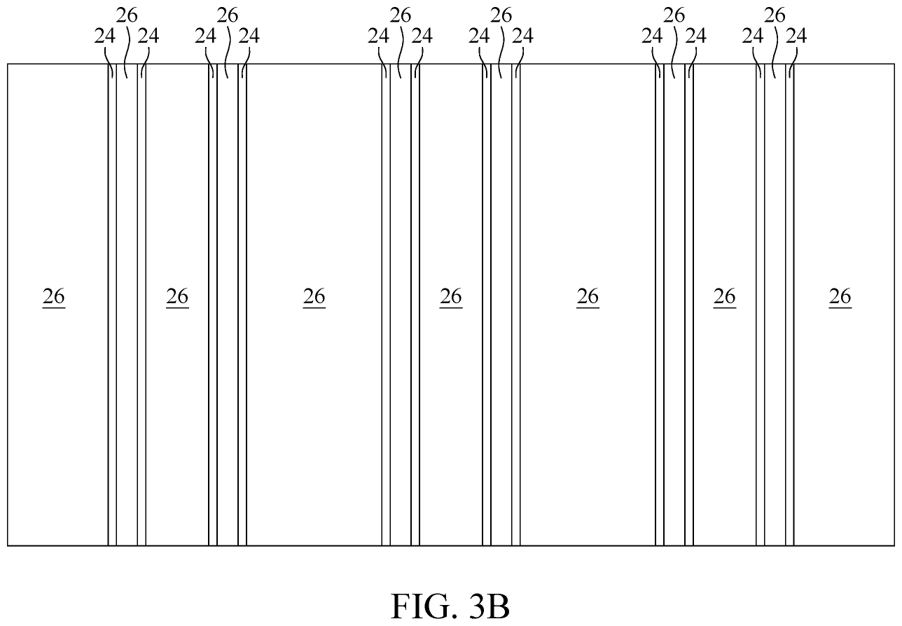

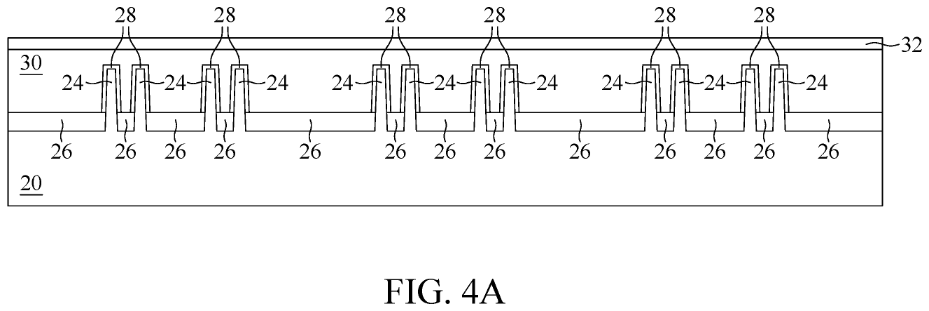

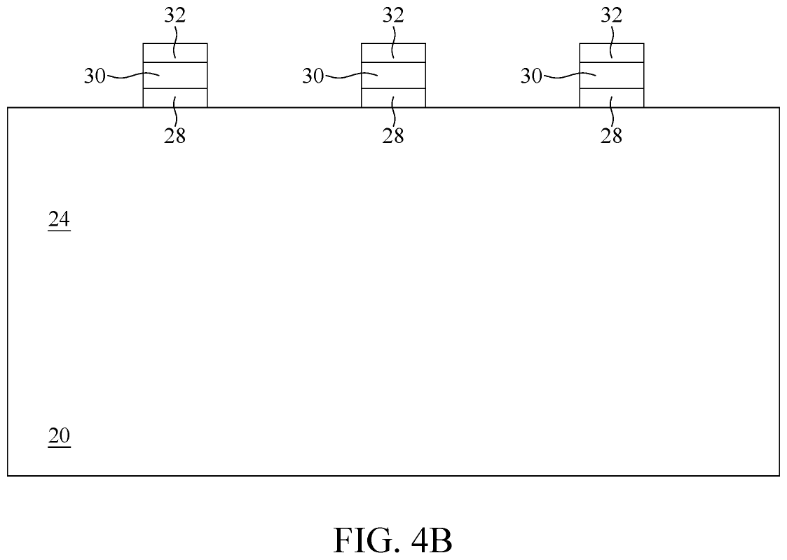

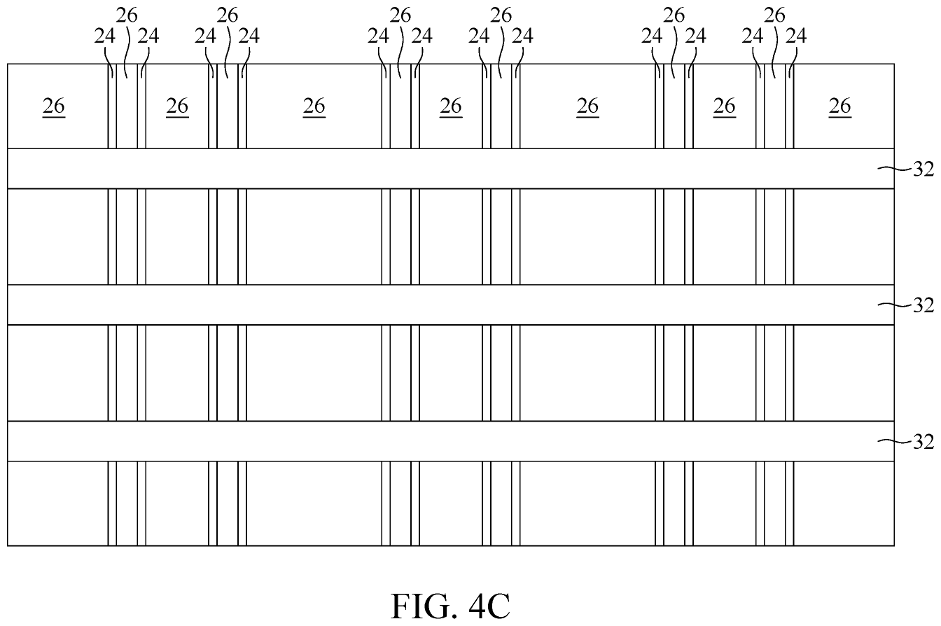

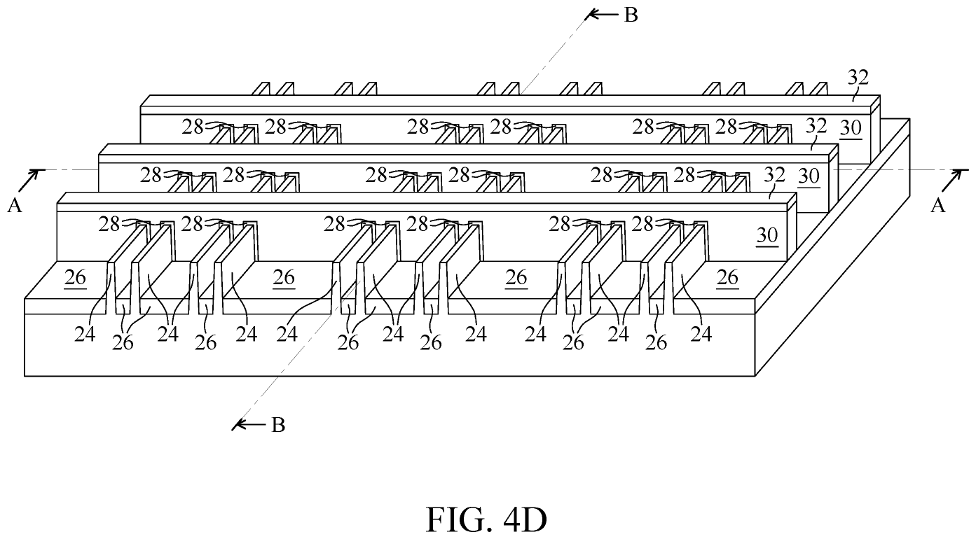

FIGS. 3A and 3B illustrate, in a cross-sectional view and top view, respectively, the formation of isolation regions 26, each in a corresponding trench. The isolation regions 26 may include or be an insulating material, such as an oxide (such as silicon oxide), a nitride, the like, or a combination thereof, and the insulating material may be formed by a high density plasma CVD (HDP-CVD), a flowable CVD (FCVD) (e.g., a CVD-based material deposition in a remote plasma system and post curing to make it convert to another material, such as an oxide), the like, or a combination thereof. Other insulating materials formed by any acceptable process may be used. In the illustrated embodiment, the isolation regions 26 include silicon oxide that is formed by a FCVD process. A planarization process, such as a CMP, may remove any excess insulating material and any remaining mask (e.g., used to form the trenches and the fins 24) to form coplanar top surfaces of the insulating material and the fins 24. The insulating material may then be recessed to form the isolation regions 26. The insulating material is recessed such that the fins 24 protrude from between neighboring isolation regions 26, which may, at least in part, thereby delineate the fins 24 as active areas on the semiconductor substrate 20. The insulating material may be recessed using an acceptable dry or wet etch process, such as one that is selective to the material of the insulating material. Further, top surfaces of the isolation regions 26 may have a flat surface as illustrated, a convex surface, a concave surface (such as dishing), or a combination thereof, which may result from an etch process. As illustrated in the top view of FIG. 3B, the fins 24 extend longitudinally across the semiconductor substrate 20. The fins 24 may have a height in a range from about 30 nm to about 50 nm from top surfaces of respective neighboring isolation regions 26. For example, the interface between the stressed semiconductor layer 22 and the semiconductor substrate 20 corresponding to each fin 24 can be below top surfaces of the isolation regions 26.

A person having ordinary skill in the art will readily understand that the processes described with respect to FIGS. 1 through 3A-B are just examples of how fins 24 may be formed. In other embodiments, a dielectric layer can be formed over a top surface of the semiconductor substrate 20; trenches can be etched through the dielectric layer; homoepitaxial structures can be epitaxially grown in the trenches (e.g., without stress engineering); and the dielectric layer can be recessed such that the homoepitaxial structures protrude from the dielectric layer to form fins. In still other embodiments, heteroepitaxial structures can be used for the fins. For example, the fins 24 can be recessed (e.g., after planarizing the insulating material of the isolation regions 26 and before recessing the insulating material), and a material different from the fins may be epitaxially grown in their place. In an even further embodiment, a dielectric layer can be formed over a top surface of the semiconductor substrate 20; trenches can be etched through the dielectric layer; heteroepitaxial structures can be epitaxially grown in the trenches using a material different from the semiconductor substrate 20 (e.g., with stress engineering); and the dielectric layer can be recessed such that the heteroepitaxial structures protrude from the dielectric layer to form fins. In some embodiments where homoepitaxial or heteroepitaxial structures are epitaxially grown, the grown materials may be in situ doped during growth, which may obviate prior implanting of the fins although in situ and implantation doping may be used together. Still further, it may be advantageous to epitaxially grow a material for an n-type device different from the material in for a p-type device.

FIGS. 4A, 4B, 4C and 4D illustrate the formation of dummy gate stacks on the fins 24. FIGS. 4A and 4B illustrate cross-sectional views; FIG. 4C illustrates a top view; and FIG. 4D illustrates a perspective view. FIG. 4D illustrates cross-sections A-A and B-B. FIGS. 1, 2, 3A, 4A, and the following figures (up to FIGS. 8A-C) ending with an “A” designation illustrate cross-sectional views at various instances of processing corresponding to cross-section A-A, and FIG. 4B and the following figures (up to FIGS. 8A-C) ending with a “B” designation illustrate cross-sectional views at various instances of processing corresponding to cross-section B-B. In some figures, some reference numbers of components or features illustrated therein may be omitted to avoid obscuring other components or features; this is for case of depicting the figures.

The dummy gate stacks are over and extend laterally perpendicularly to the fins 24. Each dummy gate stack, or more generally, gate structure, includes one or more interfacial dielectrics 28, a dummy gate 30, and a mask 32. The one or more interfacial dielectrics 28, dummy gates 30, and mask 32 for the dummy gate stacks may be formed by sequentially forming respective layers, and then patterning those layers into the dummy gate stacks. For example, a layer for the one or more interfacial dielectrics 28 may include or be silicon oxide, silicon nitride, the like, or multilayers thereof, and may be thermally and/or chemically grown on the fins 24, as illustrated, or conformally deposited, such as by plasma-enhanced CVD (PECVD), ALD, or another deposition technique. A layer for the dummy gates 30 may include or be silicon (e.g., polysilicon) or another material deposited by CVD, PVD, or another deposition technique. A layer for the mask 32 may include or be silicon nitride, silicon oxynitride, silicon carbon nitride, the like, or a combination thereof, deposited by CVD, PVD, ALD, or another deposition technique. The layers for the mask 32, dummy gates 30, and one or more interfacial dielectrics 28 may then be patterned, for example, using photolithography and one or more etch processes, like described above, to form the mask 32, dummy gate 30, and one or more interfacial dielectrics 28 for each dummy gate stack.

In some embodiments, after forming the dummy gate stacks, lightly doped drain (LDD) regions (not specifically illustrated) may be formed in the fins 24. For example, dopants may be implanted into the fins 24 using the dummy gate stacks as masks. Example dopants for the LDD regions can include or be, for example, boron for a p-type device and phosphorus or arsenic for an n-type device, although other dopants may be used. The LDD regions may have a dopant concentration in a range from about 10¹⁵ cm⁻³ to about 10¹⁷ cm⁻³.

The cross-section A-A is along a gate stack through which a cut will be made in subsequent figures and description. The cross-section B-B is along a fin 24 (e.g., along a channel direction in the fin 24) through which a cut will be made in subsequent figures and description. Cross-sections A-A and B-B are perpendicular to each other.

FIGS. 5A, 5B, and 5C illustrate the formation of gate spacers 34. Gate spacers 34 are formed along sidewalls of the dummy gate stacks (e.g., sidewalls of the one or more interfacial dielectrics 28, dummy gates 30, and masks 32) and over the fins 24. Additionally, residual gate spacers 34 may be formed along exposed sidewalls of the fins 24, as illustrated in the figures. The gate spacers 34 may be formed by conformally depositing one or more layers for the gate spacers 34 and anisotropically etching the one or more layers, for example. The one or more layers for the gate spacers 34 may include or be silicon nitride, silicon oxynitride, silicon carbon nitride, silicon oxycarbide, the like, multi-layers thereof, or a combination thereof, and the etch process can include a RIE, NBE, or another etch process.

Epitaxy source/drain regions 36 are then formed in the fins 24. Recesses for epitaxy source/drain regions 36 are formed in the fins 24 on opposing sides of the dummy gate stacks. The recessing can be by an etch process. The etch process can be isotropic or anisotropic, or further, may be selective with respect to one or more crystalline planes of the stressed semiconductor layer 22 and/or semiconductor substrate 20. Hence, the recesses can have various cross-sectional profiles based on the etch process implemented. The etch process may be a dry etch process, such as a RIE, NBE, or the like, or a wet etch process, such as using tetramethyalammonium hydroxide (TMAH), ammonium hydroxide (NH₄OH), or another etchant. The recesses may extend to a depth in a range from about 0 nm to about 80 nm from respective top surfaces of the fins 24 into the fins 24. For example, the recesses may, in some instances, not extend below a level of top surfaces of neighboring isolation regions 26 and/or below the interface between the stressed semiconductor layer 22 and the semiconductor substrate 20; although in other instances, the recesses may extend below a level of top surfaces of neighboring isolation regions 26 and/or the interface.

Epitaxy source/drain regions 36 are formed in the recesses in the fins 24. The epitaxy source/drain regions 36 may include or be silicon germanium (Si₁₋ₓGeₓ, where x can be between approximately 0 and 100), silicon carbide, silicon phosphorus, silicon carbon phosphorus, pure or substantially pure germanium, a III-V compound semiconductor, a II-VI compound semiconductor, or the like. For example, materials for forming a III-V compound semiconductor include InAs, AlAs, GaAs, InP, GaN, InGaAs, InAlAs, GaSb, AlSb, AlP, GaP, and the like. The epitaxy source/drain regions 36 may be formed in the recesses by epitaxially growing a material in the recesses, such as by MOCVD, MBE, LPE, VPE, SEG, the like, or a combination thereof. Due to blocking by the isolation regions 26 and/or residual gate spacers 34 depending on the depth of the recess in which the epitaxy source/drain region 36 is formed, epitaxy source/drain regions 36 may be first grown vertically in recesses, during which time the epitaxy source/drain regions 36 do not grow horizontally. After the recesses within the isolation regions 26 and/or residual gate spacers 34 are fully filled, the epitaxy source/drain regions 36 may grow both vertically and horizontally to form facets, which may correspond to crystalline planes of the semiconductor substrate 20. Epitaxy source/drain regions 36 may be raised in relation to the fin 24, as illustrated by dashed lines in FIG. 5B. In some examples, different materials are used for epitaxy source/drain regions for p-type devices and n-type devices. Appropriate masking during the recessing or epitaxial growth may permit different materials to be used in different devices. In this disclosure, a source region and a drain region are interchangeably used, and the structures thereof are substantially the same. Furthermore, source/drain region(s) may refer to a source or a drain, individually or collectively dependent upon the context.

FIGS. 6A, 6B, and 6C illustrate the formation of a contact etch stop layer (CESL) 38 and an interlayer dielectric (ILD) 40. The CESL 38 may be conformally deposited over the fins 24, dummy gate stacks, gate spacers 34, and isolation regions 26. The CESL 38 may include or be silicon nitride, silicon carbon nitride, silicon carbon oxide, carbon nitride, the like, or a combination thereof, and may be deposited by CVD, PECVD, ALD, or another deposition technique. The ILD 40 is deposited over the CESL 38. The ILD 40 may include or be silicon dioxide, a low-k dielectric material (e.g., a material having a dielectric constant lower than silicon dioxide), such as silicon oxynitride, phosphosilicate glass (PSG), borosilicate glass (BSG), borophosphosilicate glass (BPSG), undoped silicate glass (USG), fluorinated silicate glass (FSG), organosilicate glasses (OSG), SiOxCy, Spin-On-Glass, Spin-On-Polymers, silicon carbon material, a compound thereof, a composite thereof, the like, or a combination thereof. The ILD 40 may be deposited by spin-on, CVD, FCVD, PECVD, PVD, or another deposition technique.

The CESL 38 and ILD 40 are formed with top surfaces coplanar with top surfaces of the dummy gates 30. A planarization process, such as a CMP, may be performed to level the top surfaces of the ILD 40 and CESL 38 with the top surfaces of the dummy gates 30. The CMP may also remove the mask 32 (and, in some instances, upper portions of the gate spacers 34) on the dummy gates 30. Accordingly, top surfaces of the dummy gates 30 are exposed through the ILD 40 and CESL 38.

FIGS. 7A, 7B, and 7C illustrate the removal of the dummy gate stacks. The dummy gates 30 and one or more interfacial dielectrics 28 are removed, such as by one or more etch processes. The dummy gates 30 may be removed by an etch process selective to the dummy gates 30, wherein the one or more interfacial dielectrics 28 act as ESLs, and subsequently, the one or more interfacial dielectrics 28 can be removed by a different etch process selective to the one or more interfacial dielectrics 28. The etch processes can be, for example, a RIE, NBE, a wet etch process, or another etch process. Recesses 42 are formed between gate spacers 34 where the dummy gate stacks are removed, and channel regions of the fins 24 are exposed through the recesses 42. In some embodiments, the interfacial dielectrics 28 are not removed.

FIGS. 8A, 8B, and 8C illustrate the formation of replacement gate structures in the recesses 42. The replacement gate structures each include a gate dielectric layer 44, one or more optional conformal layers 46, and a gate electrode 48.

The gate dielectric layer 44 is conformally deposited in the recesses 42 (e.g., on top surfaces of the isolation regions 26, sidewalls and top surfaces of the fins 24 (or the interfacial dielectrics 28 if not removed) along the channel regions, and sidewalls of the gate spacers 34) and on the top surfaces of the gate spacers 34, the CESL 38, and ILD 40. The gate dielectric layer 44 can be or include silicon oxide, silicon nitride, a high-k dielectric material, multilayers thereof, or other dielectric material. A high-k dielectric material may have a k value greater than about 7.0, and may include a metal oxide of or a metal silicate of hafnium (Hf), aluminum (Al), zirconium (Zr), lanthanum (La), magnesium (Mg), barium (Ba), titanium (Ti), lead (Pb), multilayers thereof, or a combination thereof. The gate dielectric layer 44 can be deposited by ALD, PECVD, MBD, or another deposition technique.

Then, the one or more optional conformal layers 46 can be conformally (and sequentially, if more than one) deposited on the gate dielectric layer 44. The one or more optional conformal layers 46 can include one or more work-function tuning layers. The one or more work-function tuning layer may include or be a nitride, silicon nitride, carbon nitride, aluminum nitride, aluminum oxide, and/or aluminum carbide of titanium and/or tantalum; a carbide of tungsten; cobalt; platinum; the like; or a combination thereof; and may be deposited by ALD, PECVD, MBD, or another deposition technique.

A layer for the gate electrodes 48 is formed over the gate dielectric layer 44 and, if implemented, the one or more optional conformal layers 46. The layer for the gate electrodes 48 can fill remaining recesses 42 where the dummy gate stacks were removed. The layer for the gate electrodes 48 may be or include a metal-containing material such as tungsten, cobalt, aluminum, ruthenium, copper, multi-layers thereof, a combination thereof, or the like. The layer for the gate electrodes 48 can be deposited by ALD, PECVD, MBD, PVD, or another deposition technique.

Portions of the layer for the gate electrodes 48, one or more optional conformal layers 46, and gate dielectric layer 44 above the top surfaces of the ILD 40, CESL 38, and gate spacers 34 are removed. For example, a planarization process, like a CMP, may remove the portions of the layer for the gate electrodes 48, one or more optional conformal layers 46, and gate dielectric layer 44 above the top surfaces of the ILD 40, CESL 38, and gate spacers 34. Each replacement gate structure including the gate electrode 48, one or more optional conformal layers 46, and gate dielectric layer 44 may therefore be formed as illustrated in FIG. 8A-C.

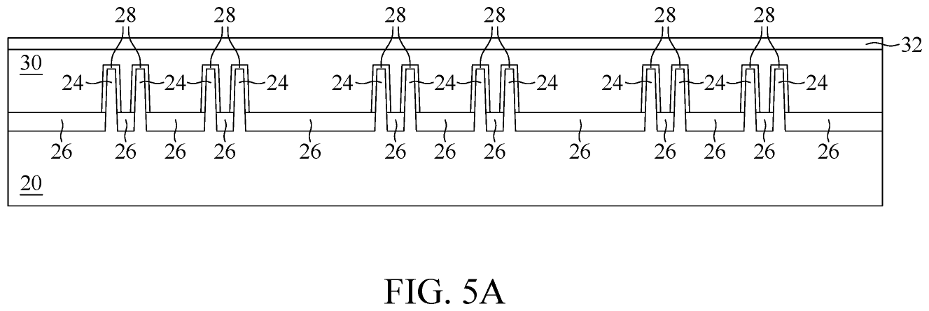

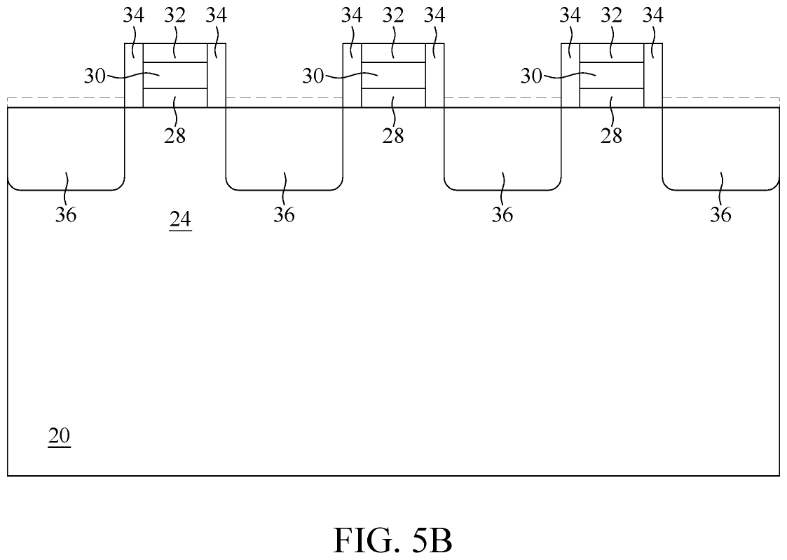

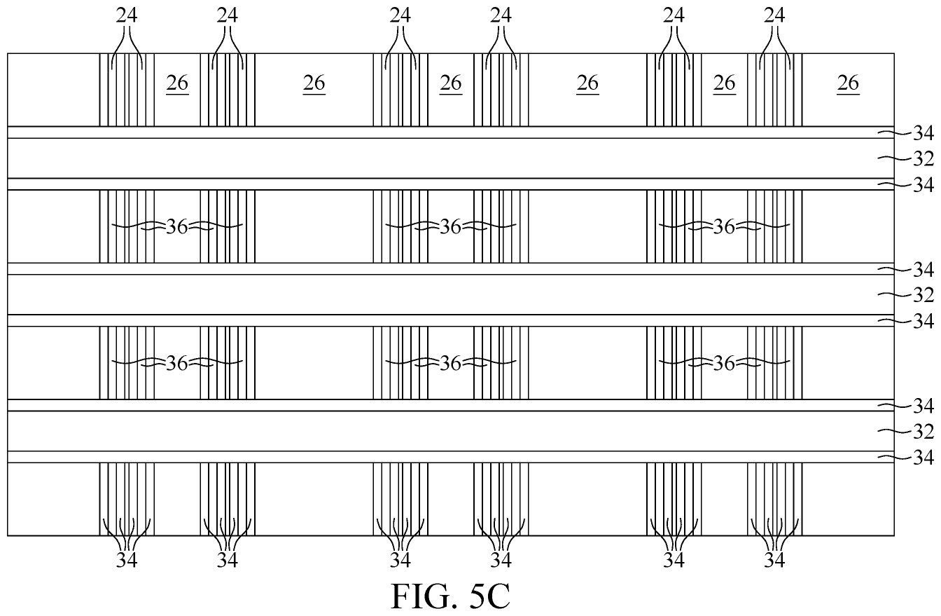

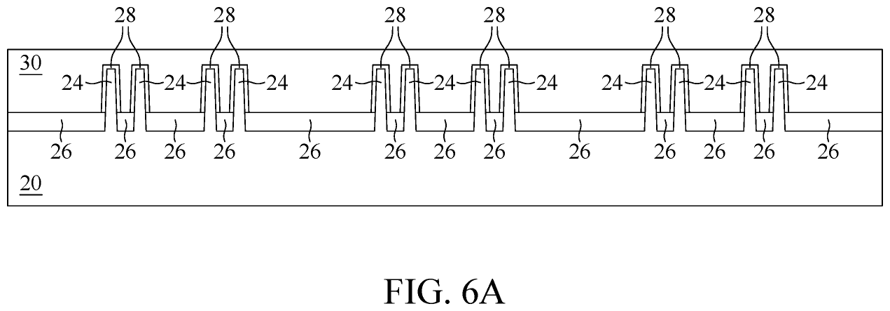

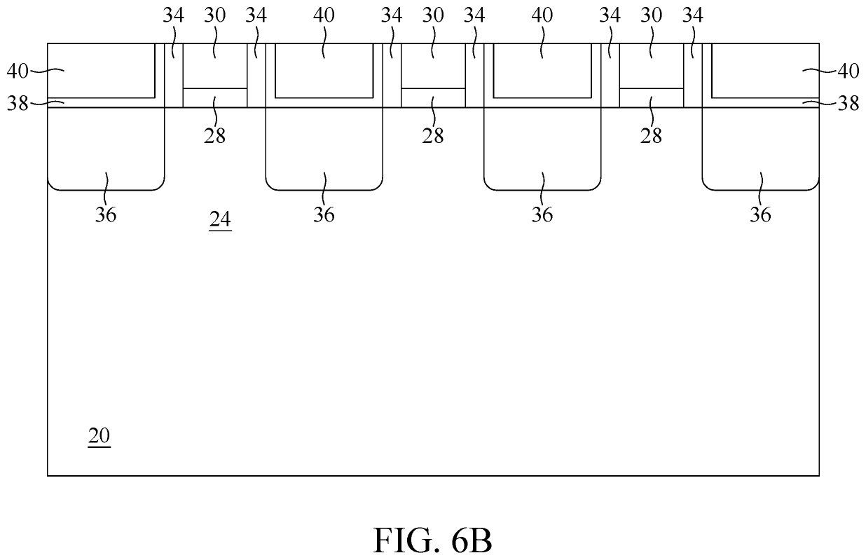

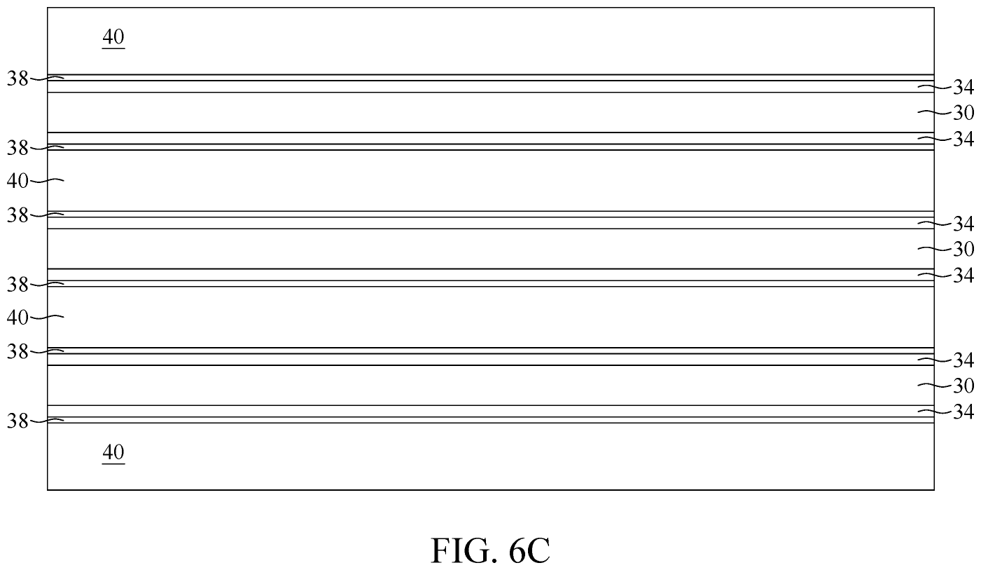

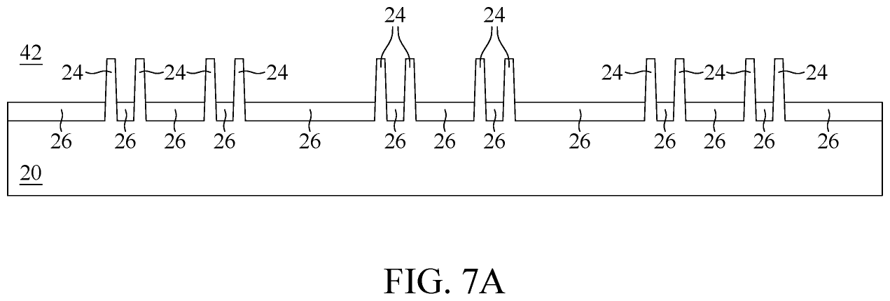

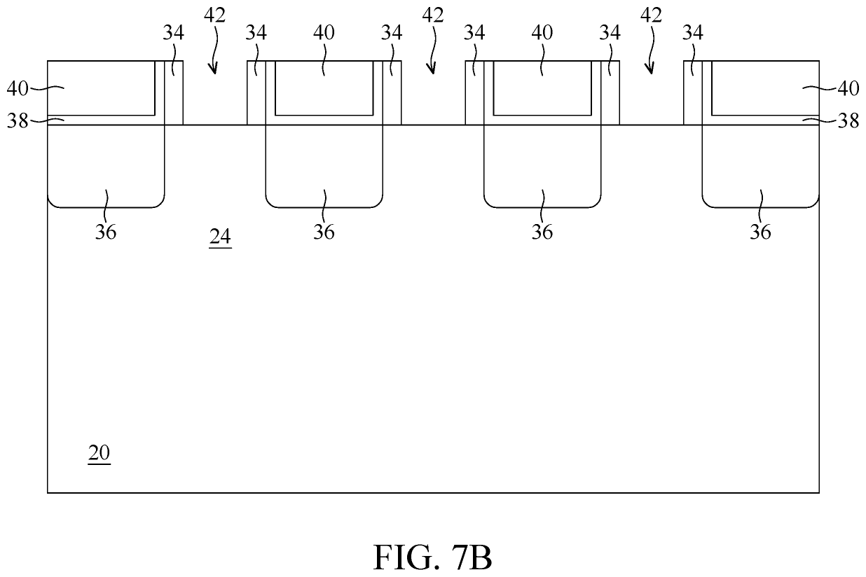

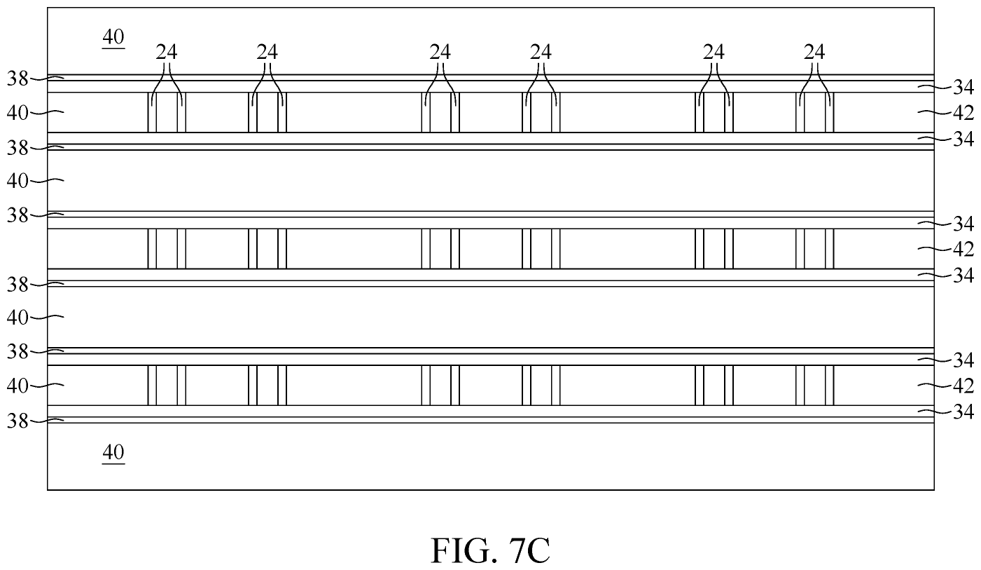

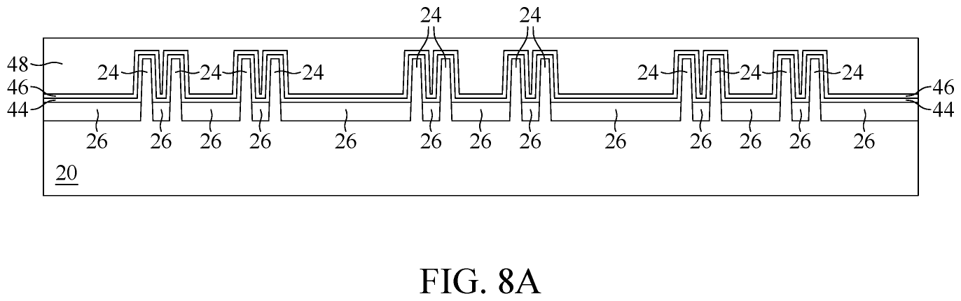

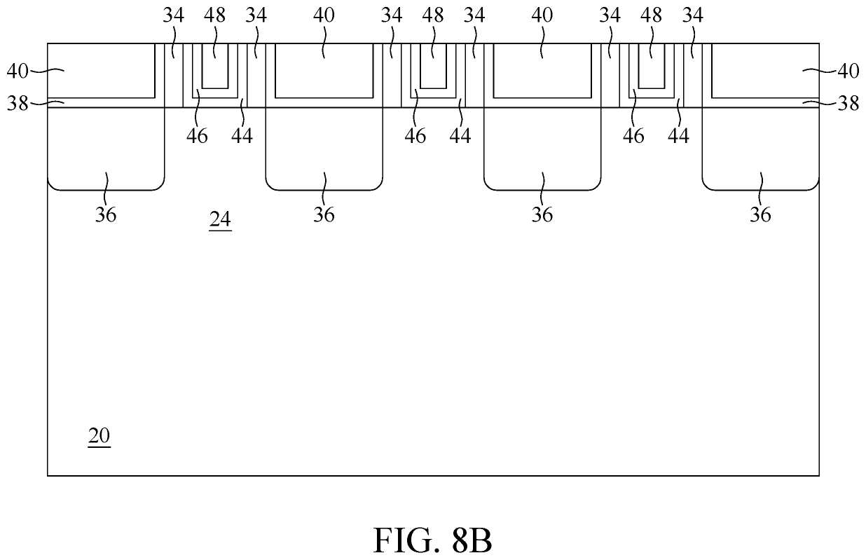

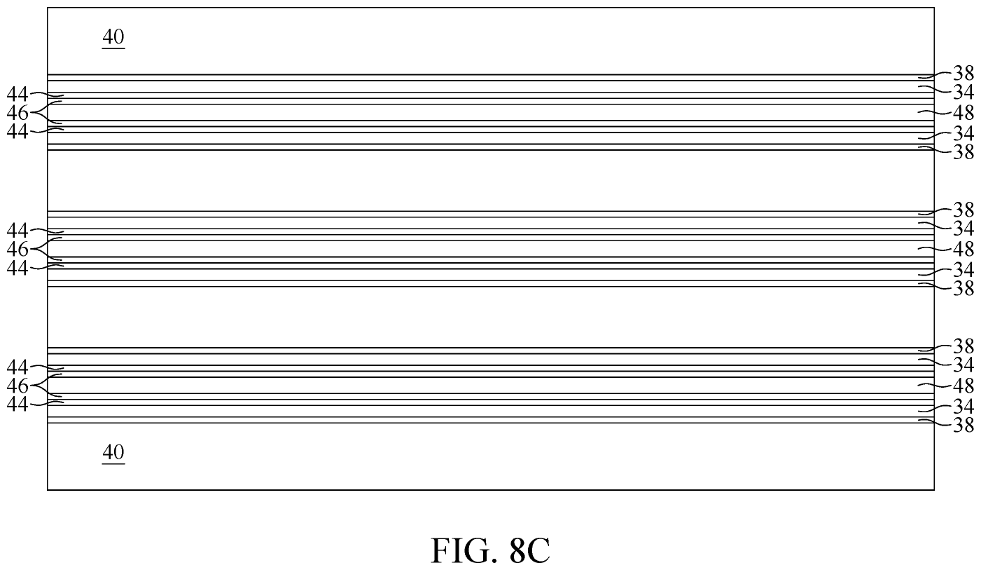

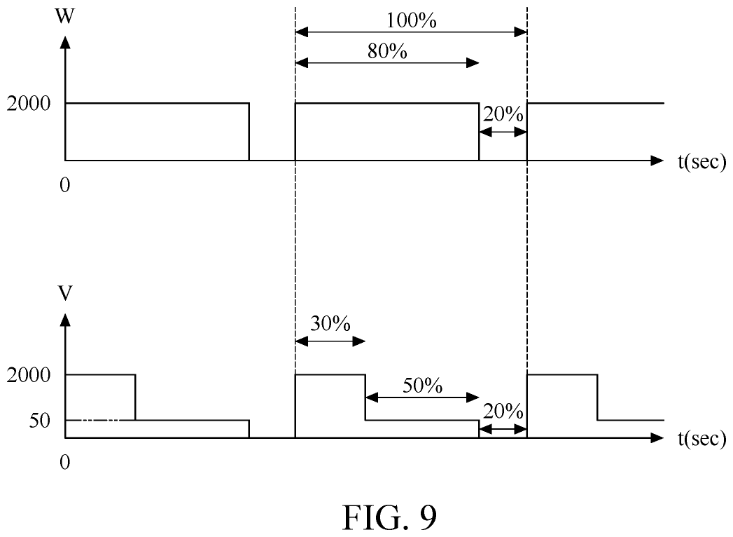

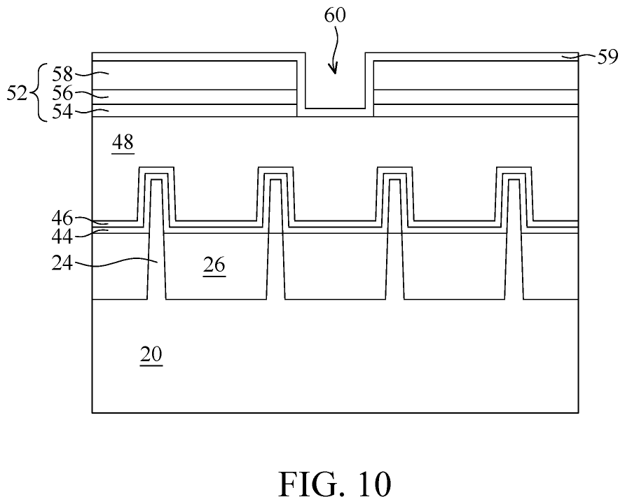

FIG. 9 shows a pulsing scheme for the process of etching the gate electrode 48, and FIGS. 10-13 are cross-sectional views at various instances of processing corresponding to cross-section A-A in FIG. 4D, in accordance with some embodiments. In FIG. 10, a mask structure 52 is formed on the gate electrodes 48. The mask structure 52 may also be formed on the ILD 40. The mask structure 52 includes one or more layers 54, 56, 58. In some embodiments, the layer 54 includes SiN, the layer 56 includes amorphous silicon, and the layer 58 includes SiN. The mask structure 52 may include more or less layers. The mask structure 52 is patterned with one or more openings 60 to expose portions of the gate electrodes 48. In some embodiments, as shown in FIG. 10, a hard mask layer 59, for example, a SiN layer, is conformally formed on the exposed surface of the gate electrode 48 and the sidewall of the mask structure 52 exposed within the opening 60.

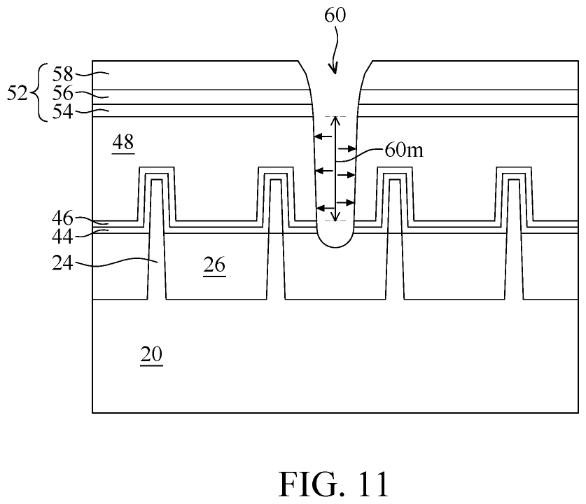

An etching process is performed to remove the gate electrode 48 within the opening 60. The hard mask layer 59 and a portion of the mask structure 52 may also be removed by the etching process. As shown in FIG. 11, the etching process extends the opening 60 to or slightly below the bottom of the remaining gate electrode 48. The profile of the extended portion 60m of the opening 60 may affect the subsequent processes. For example, if the extended portion 60m has a bowling profile, a large void may exist in a refill material formed subsequently in the opening 60. The existence of the large void within the refill material may cause some portions of the refill material as thin as weak points. The weak points not only result in a poor isolation between metal gates, but may also be punched through to cause missing metal gate in the continuous cut-metal on oxide definition edge (CMODE) process performed subsequently. The poor isolation and the missing metal gate may degrade the device performance and result in low yield.

According to some embodiments, a combination of a main etch step and a breakthrough (BT) etch step are provided to etch the gate electrode with a desired profile that minimizes the size of a void, if any, within the dielectric layer that refills the opening. The main etch step may be performed using a mixture of etching gases, including SiCl₄, BCl₃, N₂. Cl₂, and He with a processing pressure of about 20 mTorr. The processing pressure may be adjusted by a value ranging from about −20 mTorr to about 20 mTorr. A plasma source, for example, a transformer coupled plasma (TCP), may be used to generate ions from the gas mixture. The TCP power may be controlled within a range from about 1500 W to about 2500 W. In some embodiments, the TCP power may be controlled at about 2000 W. A bias power is also applied to pull the ions towards the gate electrodes 48. It has been observed that the etching angle with respect to a vertical line is dependent on the frequency of the bias power. That is, by selecting an appropriate frequency, the ratio of the lateral etching to the vertical etching may be controlled, such that a predetermined profile of the opening 60m extending through the gate electrode 48 may be obtained. According to some embodiments, the bias power with a frequency of about 1 MHz is applied to control lateral etch on the gate electrode 48 as shown by the horizontal arrows in FIG. 11.

FIG. 9 shows a pulsing scheme of the TCP power and the bias power of the main etch step for etching the gate electrode 48 according to some embodiments. The TCP power has an 80% duty cycle (DC) at a power level of about 2000 W. That is, the TCP power is controlled at a power level of about 2000 W for 80% of the time in each period and switched off (0 W) for the remaining time, that is, 20% of the time, in each period. The power level may be adjusted by a value ranging from +500 W to about −500 W according to some embodiments. The bias power also has an 80% duty cycle. That is, the bias power is switched on for 80% of the time in each period and switched off for 20% of the time in each period. However, the voltage level of the bias power for the first 30% is controlled at about 200 V, while the voltage level drops to about 50 V for the following 50% in each period. Each voltage level may be adjusted with a voltage value ranging from about +50 V to about −50V. In some embodiments, the voltage for the following 50% in each period ranges from about 5 V to about 100V. The 30% duty cycle may be adjusted with a percentage ranging from about +30% to about −30%, while the 50% duty cycle may be adjusted with a percentage ranging from about +40% to about −40%. The off cycle may also be adjusted with a percentage ranging from about +20% to about −20%. The parameters of the plasma etching process for etching the gate electrode 48 are listed in Table I presented below.

TABLE I

| Bias State | 1 | 2 | 3 |
|---|---|---|---|
| DC (%) | 30 ± 30 | 50 ± 40 | 20 ± 20 |
| TCP Power (W) | 2000 ± 500 | 2000 ± 500 | 0 ± 500 |
| Bias Power (1 MHz) | 200 ± 50 | 50 ± 50 | 0 ± 50 |
| (V) | | | |

| | |
|---|---|
| Pressure (mTorr) | 20 ± 20 |
| Gas | SiCl₄/BCl₃/N₂/Cl₂/He |

The main etch step with the pulsing scheme as shown in FIG. 9 and the etching conditions as shown in Table I provide a control of substantially lateral etch as indicated by the horizontal arrows as shown in FIG. 11. The gate electrode 48 is etched with a tapered profile that has a gradually decreasing cross section from a top to a bottom.

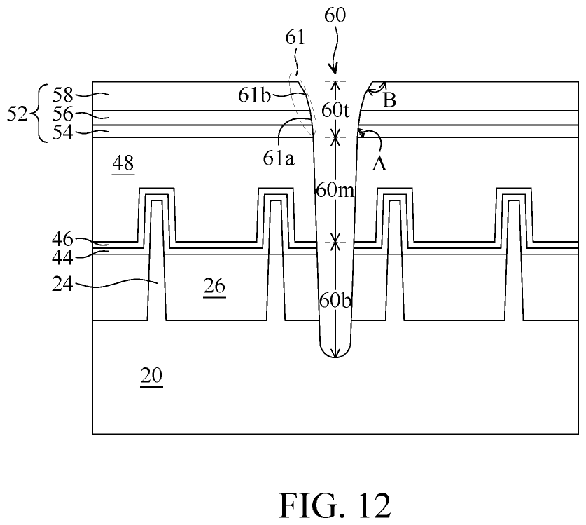

In FIG. 12, the opening 60 is further extended by etching through the isolation region 26 and a top portion of the substrate 20. The bottom portion 60b extending through the isolation region 26 and the top portion of the substrate 20 may be formed by an etching process using a gas mixture of C₄F₆, O₂, and N₂ under a pressure of about 20 mTorr±20 mTorr. The source power may be controlled with a power level of about 100 W, and a 1000 V bias power with a frequency of about 13.5 MHz may also be applied.

In FIG. 12, the sidewall 61 of the mask structure 52 exposed to the top portion 60t of the opening 60 may have a substantially straight portion 61a and a slant portion 61b. In some embodiments, an angle A is formed between a side surface of the layer 54 exposed to the top portion 60t of the opening 60 and a bottom surface of the layer 54 disposed on the gate electrode 48, and the angle A ranges from about 80 degrees to about 90 degrees. In some embodiments, an angle B is formed between a side surface of the layer 58 exposed to the top portion 60t of the opening 60 and a top surface of the layer 58, and the angle B ranges from about 100 degrees to about 120 degrees. A sharp corner may be formed at where the substantially straight portion 61a and the slant portion 61b meet. The sharp corner may hinder the flow of material to refill the opening 60 subsequently. In addition, the sharp corner may cause the refill material to merge at the top portion 60t before the middle portion 60m and the bottom portion 60b are filled completely. Similar to the bowling profile of the middle portion 60m, the sharp corner may cause the formation or further enlarge a large void within the refill material. Therefore, according to some embodiments, an additional etch step is performed after the opening 60 has extended into the substrate 20. The additional etch step may be referred to as a final breakthrough (BT) etch step for fine tuning the profile of the opening 60.

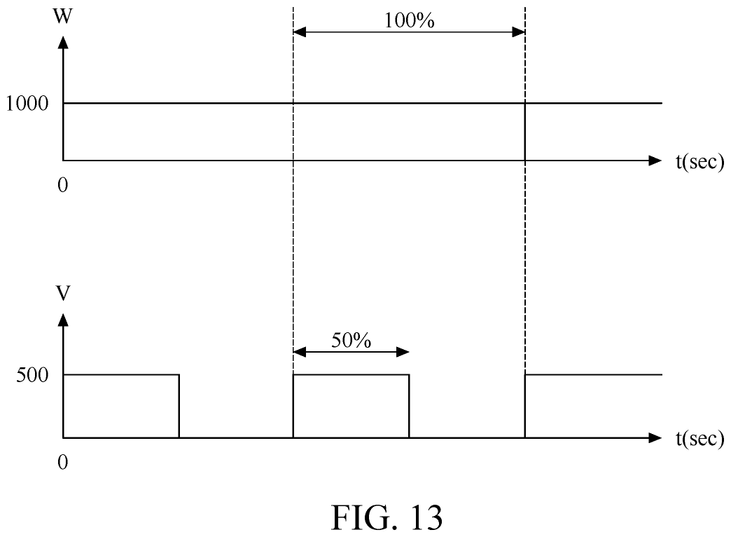

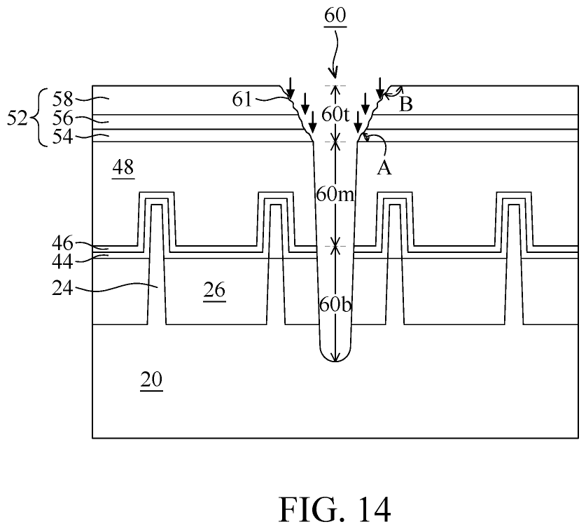

FIG. 13 shows a pulsing scheme used for performing the final BT etch step, and FIGS. 14-17 are cross-sectional views at various instances of processing corresponding to cross-section A-A in FIG. 4D, in accordance with some embodiments. The final BT step may be a plasma etching process with an always-on source power at a power level of about 100 W. That is, the source power has a 100% duty cycle at a lower level of about 100 W. The power level may be adjusted by a value ranging from about +100 W to about −100 W. In some embodiments, the power level ranges from about 10 W to about 200 W. According to some embodiments, the bias power has a frequency of about 13.5 MHz and a 50% duty cycle at a power level of about 500 V. That is, the bias power is switched on to a voltage level of about 500 V for 50% of the time in each period and switched off for 50% of the time in each period. The power level may be adjusted with a value ranging from about +300 V to about −300V. In some embodiments, the power level ranges from about 200 V to about 800 V. The etching gas may include a mixture of C₄F₆, O₂, and Ar. A pressure of about 20 mTorr±20 mTorr may be applied. The etching parameters may be controlled according to Table II presented below.

As listed in Table II, the TCP power is controlled at a power level around 100 W, and the frequency of the bias power is around 13.5 MHZ. It can be expected that the ions may stay at the top portion 60t of the opening 60 to etch the sidewall of the mask structure 52 along a substantially vertical direction as shown by the arrows as shown in FIG. 14. The parameters illustrated in Table II allow ions created by the TCP power to locate at the top portion 60t to widen and smooth the sidewall of mask structure 52 within the top portion 60t of the opening 60 without further laterally etching the gate electrode 48 and the isolation regions 26. As a result, the sharp corner in the sidewall 61 may be removed, and a substantially linear slant sidewall 61 of the mask structure 52 exposed to the top portion 60t is formed. The substantially linear sidewall 61 provides an overall funnel profile of the opening 60. In some embodiments, the angle A is substantially decreased by the final BT etch step, and the angle B is substantially enlarged by the final BT etch step. In some embodiments, the angle A after the final BT etch step ranges from about 30 degrees to about 60 degrees, and the angle B after the final B ranges from about 140 degrees to about 170 degrees. The final BT etch step modifies the profile of the mask structure 52 without substantially affect the gate electrode 48. The final BT etch step is performed after the formation of the bottom portion 60b of the opening 60 in order to protect the gate electrode 48. If the final BT etch step is performed before the etch process to form the bottom portion 60b of the opening 60, the etch process to form the bottom portion 60b of the opening 60 may remove portions of the mask structure 52, which are thinner as a result of the final BT etch step, and damage the gate electrode 48 and/or unnecessarily enlarge the critical dimension of the opening 60 in the gate electrode 48.

TABLE II

| Bias State | 1 | 2 |
|---|---|---|
| DC (%) | 50 ± 50 | 50 ± 50 |
| TCP Power (W) | 100 ± 100 | 100 ± 100 |
| Bias Power (13.5 MHz) | 500 ± 300 | 0 ± 300 |
| (V) | | |

| | |
|---|---|
| Pressure (mTorr) | 20 ± 20 |
| Gas | C₄F₆/O₂/Ar |

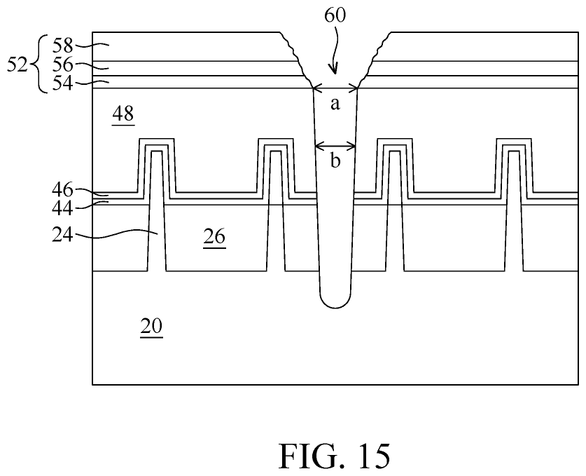

As shown in FIG. 15, the combination of the main etching step for removing the gate electrode 48 and the final BT etching step result in a funnel profile of the opening 60. The top critical dimension (TCD) “a” at the top of the metal gate, that is, the patterned gate electrode 48, is larger than the middle critical dimension (MCD) “b” at the top level of the fins 24. In some embodiments, the difference between TCD and MCD, that is, “a-b” may be improved from the range of −4 nm to −1 nm to range of −1 nm to 1 nm with the main etching process using the pulsing scheme as shown in FIG. 9 and the etching condition listed in Table I. In combination with the final BT etch step, the difference may be further improved to the range of 1 nm to 4 nm.

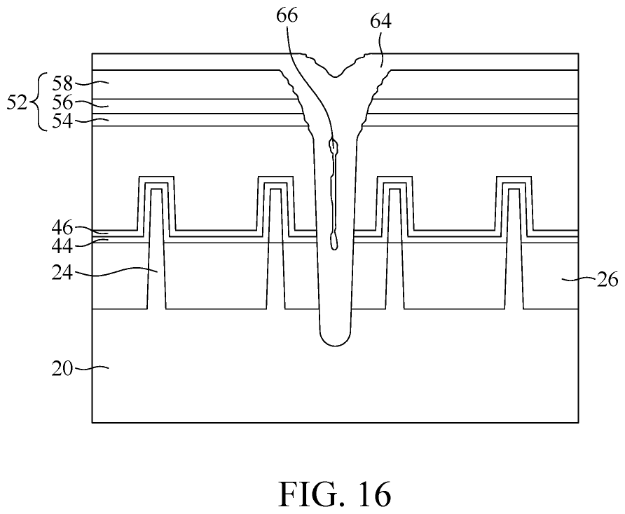

As shown in FIG. 16, a dielectric material 64 is formed in the opening 60. The dielectric material 64 may be any suitable dielectric material, such as SiN. The gapfill capability of the dielectric material 64 is poor in the high aspect ratio opening 60, and a void 66 may be formed in the dielectric material 64. In some embodiments, the void 66 has a dimension greater than about 1 nm. As discussed above, the funnel profile of the opening 60 resulted from the main etching step of the gate electrode 48 and the final BT etch step improves refill of the dielectric material 64 and thus minimizes the size of the void 66. For example, the width of void 66 may be reduced to less than 1 nm according to some embodiments.

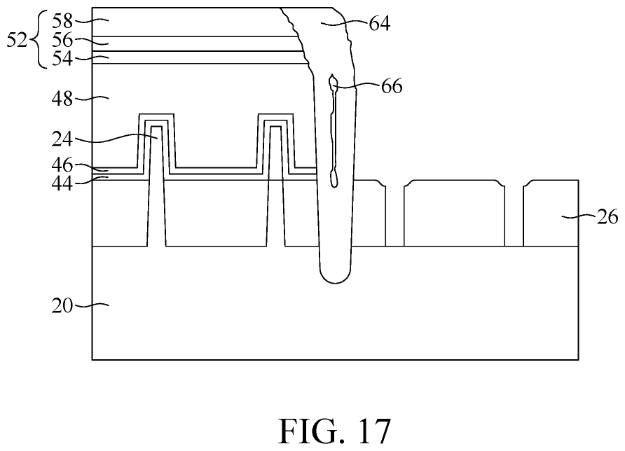

FIG. 17 shows the device after performing the CMODE process. As the size of the void 66 has been minimized, the dielectric layer 64 has a sufficient thickness to provide a good isolation between metal gates. There is no weak point to be punched by CMODE process. Therefore, the missing metal gate is prevented. A higher yield and improved device performance can thus be expected.

Embodiments of the present disclosure provide a method to form an opening 60 in a mask structure 52 and a gate electrode 48. In some embodiments, the method includes a main etch step and a final BT step. Some embodiments may achieve advantages. For example, the process conditions of the main etch step prevents bowling of the opening 60 in the gate electrode 48, while the final BT step enlarges the portion of the opening 60 in the mask structure 52. As a result, the dielectric layer 64 formed in the opening 60 includes a void 66 with reduced size.

An embodiment is a method. The method includes forming a gate electrode, forming a mask structure over the gate electrode, patterning the mask structure to form an opening, and performing a first etch process on the gate electrode by applying a first source power and a first bias power with a first pulsing scheme. The first bias power has a first frequency to control etching along a lateral direction. The method further includes performing a second etch process on the mask structure exposed within the opening by applying a second source power and a second bias power with a second pulsing scheme, and the second bias power has a second frequency to control etching along a vertical direction. The first and second frequencies are substantially different.

Another embodiment is a method. The method includes a first etch process performed on a gate electrode. The first etch process includes a plasma etch process with a first source power with an 80% duty cycle at a power level ranging from about 1500 W to about 2500 W, and a first bias power with a 30% duty cycle at a voltage level ranging from about 150 V to about 250 V and 50% duty cycle at a voltage level ranging from about 5 V to about 100 V immediately following the 30% duty cycle. The method further includes a second etch process performed on a mask structure disposed on the gate electrode. The second etch process includes a plasma etch process with a second source power with a 100% duty cycle at a power level ranging from about 10 W to about 200 W, and a second bias power with a 50% duty cycle at a voltage level ranging from about 200 V to about 800 V.

A further embodiment is a method. The method includes forming a plurality of fins from a semiconductor substrate, forming isolation regions around each fin of the plurality of fins, depositing a gate electrode over the plurality of fins, forming a mask structure over the gate electrode, forming an opening in the mask structure, extending the opening through the gate electrode by a first plasma etch process with a first bias power having a frequency to control a lateral etch of the gate electrode, extending the opening through the isolation region, etching a sidewall of the mask structure within the opening by a second plasma etch process with a second bias power having a frequency to control a vertical etch of the mask structure and to remove a sharp corner in the sidewall of the mask structure exposed to the opening, and filling the opening with a dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a gate electrode;
forming a mask structure over the gate electrode;
patterning the mask structure to form an opening;
performing a first etch process on the gate electrode by applying a first source power and a first bias power with a first pulsing scheme, wherein the first bias power has a first frequency to control etching along a lateral direction; and
performing a second etch process on the mask structure exposed within the opening by applying a second source power and a second bias power with a second pulsing scheme, wherein the second bias power has a second frequency to control etching along a vertical direction, wherein the first and second frequencies are substantially different.

2. The method of claim 1, wherein the first pulsing scheme includes an 80% duty cycle for both the first source power and the first bias power.

3. The method of claim 2, wherein the first pulsing scheme comprises:
controlling the first source power at a power level of about 2000 W in the 80% duty cycle;
controlling the first bias power at a voltage level of about 200 V in a first 30% of the 80% duty cycle; and
controlling the first bias power at a voltage level of about 50 V in a following 50% of the 80% duty cycle.

4. The method of claim 1, wherein the second pulsing scheme includes a 100% duty cycle of the second power source and a 50% duty cycle of the second bias power.

5. The method of claim 4, wherein the second pulsing scheme comprises:
controlling the second source power at a power level of about 100 W in the 100% duty cycle; and
controlling the second bias power at a voltage level of about 500 V in the 50% duty cycle.

6. The method of claim 1, wherein first frequency is about 1 MHz and the second frequency is about 13.5 MHz.

7. The method of claim 1, further comprising performing a third etch process to extend the opening through an isolation region under the gate electrode and a portion of a substrate under the isolation region before performing the second etch process.

8. The method of claim 1, further comprising forming a conformal hard mask layer after patterning the mask structure.

9. The method of claim 1, further comprising controlling the second source power at a power level and the second bias power at a voltage level to provide a fine tuning effect on a sidewall of the mask structure in the second etch process.

10. A method, comprising:
a first etch process performed on a gate electrode, wherein the first etch process includes a plasma etch process with:
a first source power with an 80% duty cycle at a power level ranging from about 1500 W to about 2500 W; and
a first bias power with a 30% duty cycle at a voltage level ranging from about 150 V to about 250 V and 50% duty cycle at a voltage level ranging from about 5 V to about 100 V immediately following the 30% duty cycle; and
a second etch process performed on a mask structure disposed on the gate electrode, wherein the second etch process includes a plasma etch process with:
a second source power with a 100% duty cycle at a power level ranging from about 10 W to about 200 W; and
a second bias power with a 50% duty cycle at a voltage level ranging from about 200 V to about 800 V.

11. The method of claim 10, wherein the first bias power has a first frequency to control a lateral etch on the gate electrode, and the second bias power has a second frequency to control a vertical etch on the mask structure.

12. The method of claim 11, wherein the first frequency is 1 MHz and the second frequency is 13.5 MHz.

13. The method of claim 10, wherein second etch process is performed after the first etch process.

14. A method, comprising:
forming a plurality of fins from a semiconductor substrate;
forming isolation regions around each fin of the plurality of fins;
depositing a gate electrode over the plurality of fins;
forming a mask structure over the gate electrode;
forming an opening in the mask structure;
extending the opening through the gate electrode by a first plasma etch process with a first bias power having a frequency to control a lateral etch of the gate electrode;
extending the opening through the isolation region;
etching a sidewall of the mask structure within the opening by a second plasma etch process with a second bias power having a frequency to control a vertical etch of the mask structure and to remove a sharp corner in the sidewall of the mask structure exposed to the opening; and
filling the opening with a dielectric layer.

15. The method of claim 14, wherein the forming the mask structure comprises:
forming a first layer;
forming a second layer on the first layer; and
forming a third layer on the second layer.

16. The method of claim 15, wherein a side surface of the first layer exposed to the opening and a bottom surface of the first layer form a first angle, and a side surface of the third layer exposed to the opening and a top surface of the third layer form a second angle.

17. The method of claim 16, wherein the first angle ranges from about 80 degrees to about 90 degrees, and the second angle ranges from about 100 degrees to about 120 degrees.

18. The method of claim 16, wherein the first angle decreases after the second plasma etch process.

19. The method of claim 18, wherein the second angle increases after the second plasma etch process.

20. The method of claim 19, wherein the first angle ranges from about 30 degrees to about 60 degrees after the second plasma etch process, and the second angle ranges from about 140 degrees to about 170 degrees after the second plasma etch process.
